(19) United States
(12) Patent Application Publication
(10) Pub. No.: US 2025/0216432 A1
(43) Pub. Date: Jul. 3, 2025

(54) DYNAMIC MEASUREMENT METHOD FOR SPATIAL MAGNETIC FIELD OF TRANSMISSION LINES BASED ON TWO-DIMENSIONAL ELECTROMAGNETIC SENSOR MATRIX

(71) Applicants: Hefei Institutes of Physical Science, Chinese Academy of Sciences, Hefei City (CN); Anhui Electric Power Transmission and Transformation Co., Ltd., Hefei City (CN)

(72) Inventors: Xiuqing Zhang, Hefei City (CN); Xiaojiao Chen, Hefei City (CN); Shizhong Lin, Hefei City (CN); Shiying He, Hefei City (CN); Liansheng Huang, Hefei City (CN); Youlong Yin, Hefei City (CN); Jiajie Lei, Hefei City (CN); Jiawen Xu, Hefei City (CN); Jun Liu, Hefei City (CN); Zejing Wang, Hefei City (CN); Ying Zuo, Hefei City (CN); Lingpeng Li, Hefei City (CN); Sheng Dou, Hefei City (CN); Pujian Wang, Hefei City (CN); Ying Wang, Hefei City (CN)

(21) Appl. No.: 18/774,017

(22) Filed: Jul. 16, 2024

(30) Foreign Application Priority Data
Dec. 27, 2023 (CN) 202311821312.4

(51) Int. Cl. G01R 29/08; G05D 1/247; G05D 105/80; G05D 109/20

(52) U.S. Cl. CPC G01R 29/085; G01R 29/0892; G05D 1/247; G05D 2105/89; G05D 2109/20

(57) ABSTRACT

A dynamic measurement method for spatial magnetic field of transmission lines based on two-dimensional electromagnetic sensor matrix is provided. Data measured by an electromagnetic sensor matrix parallel to the transmission lines is used to calibrate an unmanned aerial vehicle (UAV) flight status, while magnetic field distribution characteristics within a profile of the transmission lines are measured using an electromagnetic sensor matrix perpendicular to the transmission lines, thereby achieving dynamic measurement of the spatial magnetic field of the transmission lines during UAV flight. The method achieves measurement of the magnetic field distribution characteristics within the vertical profile of the transmission lines while ensuring that the UAV flies parallel to the transmission lines. The method solves the problem of dynamically measuring the magnetic field distribution during UAV flight and is significant for accurately identifying transmission lines using magnetic field distribution characteristics.

### CROSS REFERENCE TO RELATED APPLICATION

This patent application claims the benefit and priority of Chinese Patent Application No. 202311821312.4, filed with the China National Intellectual Property Administration on Dec. 27, 2023, the disclosure of which is incorporated by reference herein in its entirety as part of the present application.

### TECHNICAL FIELD

The present disclosure relates to the technical field of measurement for spatial magnetic field distribution characteristics of transmission lines, and in particular, to a dynamic measurement method for a spatial magnetic field of transmission lines based on a two-dimensional electromagnetic sensor matrix.

### BACKGROUND

In the field of unmanned aerial vehicle (UAV) transmission line inspection applications, it is necessary to consider the impact of the magnetic field distribution of transmission lines on the safe flight of UAVs and how to use magnetic field distribution characteristics to identify and track transmission lines. Currently, existing methods for measuring the magnetic field of transmission lines only measure the magnetic field magnitude at a certain distance from the transmission lines to determine if it is within a safe range. The existing methods cannot analyze magnetic field distribution characteristics in a vertical profile of transmission lines, failing to identify the transmission lines based on multidimensional measurements of magnetic field distribution characteristics.

### SUMMARY

To solve the above technical problem, the present disclosure provides a dynamic measurement method for a spatial magnetic field of transmission lines based on a two-dimensional electromagnetic sensor matrix, which measures magnetic field distribution characteristics within a vertical profile of the transmission lines while considering the calibration of the UAV flight status.

In order to achieve the above objectives, the present disclosure adopts the following technical solution: A dynamic measurement method for a spatial magnetic field of transmission lines based on a two-dimensional electromagnetic sensor matrix is provided. A first electromagnetic sensor matrix is arranged parallel to transmission lines and is used for calibrating a UAV flight status, while a second electromagnetic sensor matrix is arranged perpendicular to the transmission lines and is used for measuring magnetic field distribution characteristics within a vertical profile of the transmission lines. The first electromagnetic sensor matrix parallel to the transmission lines and the second electromagnetic sensor matrix perpendicular to the transmission lines form a two-dimensional electromagnetic sensor matrix. Dynamic measurement for a spatial magnetic field of the transmission lines is achieved through the two-dimensional electromagnetic sensor matrix during UAV flight.

Further, the calibration of the UAV flight status includes: measuring a magnetic field distribution parallel to the transmission lines by using k electromagnetic sensors in each row of electromagnetic sensor matric containing j rows, where if results measured by the k electromagnetic sensors in each row are consistent, it indicates that a UAV is flying along a position parallel to the transmission lines, and if the results are inconsistent, the UAV flight status is adjusted; measuring a magnetic field distribution parallel to the transmission lines by using j electromagnetic sensors in each column of electromagnetic sensor matric containing k columns, and analyzing a magnetic field gradient direction to determine whether it is necessary to adjust a flight altitude of the UAV to keep the UAV at an altitude the same as the transmission lines.

Further, the second electromagnetic sensor matrix is an m×n order matrix, where m and n are both natural numbers, with m as the number of rows, preferably in a range of [3, 5], and n as the number of columns, preferably in a range of [5, 10]. The magnetic field distribution characteristics within the vertical profile of the transmission lines are dynamically measured using m×n electromagnetic sensors, and by normalizing m×n discrete values, the spatial magnetic field gradient direction within the vertical profile of the transmission lines is calculated, thereby identifying the position of the transmission lines based on the characteristic that the magnetic field gradient direction points towards the transmission lines.

Further, the normalization is performed using the following formula:

$${X}^{*} = \frac{X - {X}_{min}}{{X}_{max} - {X}_{min}}$$

where Xₘₐₓ represents a maximum sample value, Xₘᵢₙ represents a minimum sample value, X represents an original sample value, and X* represents a normalized sample value.

Further, the dynamic measurement includes dynamically measuring a gradient amplitude value and a gradient direction of the spatial magnetic field of the transmission lines by using m rows of electromagnetic sensors and n columns of electromagnetic sensors arranged laterally in the second electromagnetic sensor matrix perpendicular to the transmission lines, where a calculation formula is as follows:

$$\{ \begin{matrix}{G}_{x} ( x , y ) = H ( x + 1 , y ) - H ( x - 1 , y ) \\ {G}_{y} ( x , y ) = H ( x , y + 1 ) - H ( x , y - 1 )\end{matrix}$$

$$G ( x , y ) = \sqrt{{G}_{x}^{2} ( x , y ) + {G}_{y}^{2} ( x , y )}$$

$$α ( x , y ) = {tan}^{- 1} \frac{{G}_{y} ( x , y )}{{G}_{x} ( x , y )}$$

where H(x, y) represents a characteristic value of a magnetic field at (x, y), Gₓ(x, y) represents a lateral gradient of the magnetic field at (x, y), G_{y}(x, y) represents a longitudinal gradient of the magnetic field at (x, y), G(x, y) represents a gradient amplitude value of the magnetic field at (x, y), and α(x, y) represents a gradient direction of the magnetic field at (x, y). (x, y) represents a position of each electromagnetic sensor in the vertical profile of the transmission lines among the m×n electromagnetic sensors.

### Beneficial Effects

The present disclosure utilizes a two-dimensional electromagnetic sensor matrix to measure the magnetic field distribution in the direction parallel to the transmission lines and the magnetic field distribution characteristics within the vertical profile of the transmission lines. The magnetic field distribution characteristics within the vertical profile of the transmission lines are measured while ensuring that the UAV flies parallel to the transmission lines. The present disclosure solves the problem of dynamically measuring the magnetic field distribution during UAV flight and is significant for accurately identifying transmission lines using magnetic field distribution characteristics.

### BRIEF DESCRIPTION OF THE DRAWINGS

FIG. 1 is a schematic diagram of a measurement apparatus based on a two-dimensional electromagnetic sensor matrix in the present disclosure,
where 1 represents a first electromagnetic sensor matrix; 2 represents a second electromagnetic sensor matrix; 3 represents a loading module of the two-dimensional electromagnetic sensor matrix; and

FIGS. 2A-2C are diagram depicting a relationship between a UAV and transmission lines, where FIG. 2A represents that the UAV is above the transmission lines, FIG. 2B represents that the UAV is below the transmission lines, and FIG. 2C represents that the UAV is flush with the transmission lines.

### DETAILED DESCRIPTION OF THE EMBODIMENTS

In order to make the objectives, technical solutions, and advantages of the present disclosure more clear, the present disclosure is further described in detail combining with the drawings and examples as follow. It should be understood that the specific examples described herein are merely intended to explain the present disclosure, but not to limit the present disclosure. Further, the technical features involved in the various embodiments of the present disclosure described below may be combined with each other as long as they do not constitute a conflict with each other.

A dynamic measurement method for a spatial magnetic field of transmission lines based on a two-dimensional electromagnetic sensor matrix of the present disclosure measures a magnetic field distribution parallel to the transmission lines and a magnetic field distribution within a vertical profile of the transmission lines by using a two-dimensional electromagnetic sensor matrix, thereby achieving dynamic measurement of the spatial magnetic field of the transmission lines during UAV flight.

The arrangement of the electromagnetic sensors of the two-dimensional electromagnetic sensor matrix is shown in FIG. 1. A loading module 3 of the two-dimensional electromagnetic sensor matrix loads a first electromagnetic sensor matrix 1 parallel to the transmission lines and a second electromagnetic sensor matrix 2 perpendicular to the transmission lines.

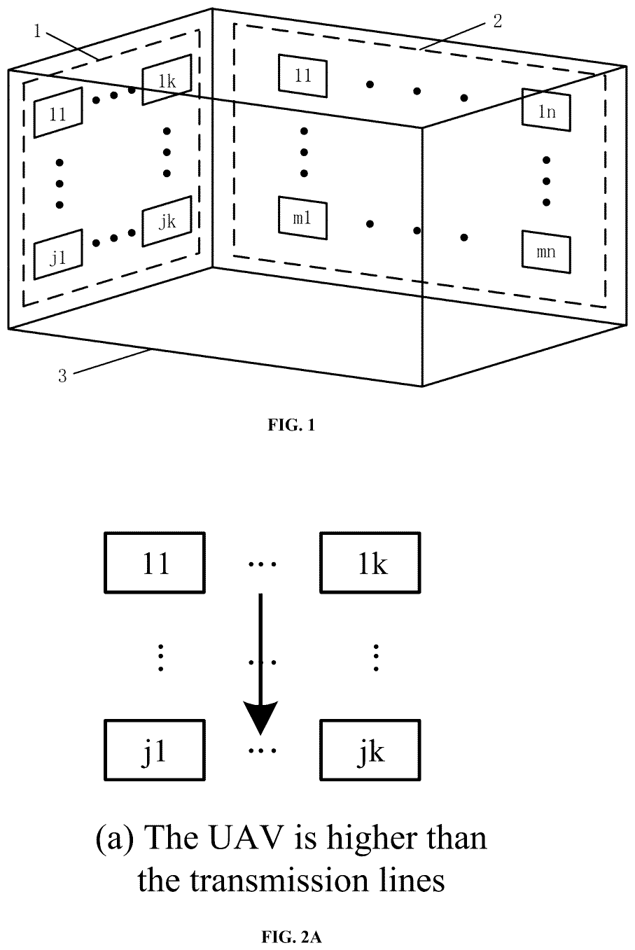

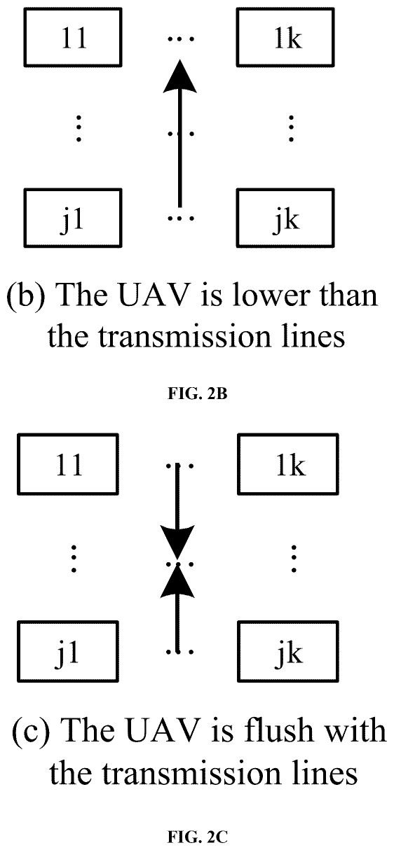

The first electromagnetic sensor matrix 1 parallel to the transmission lines is a j×k-order matrix composed of j×k electromagnetic sensors, where j and k are both natural numbers, preferably within a range of [3, 5]. The first electromagnetic sensor matrix 1 is arranged parallel to the transmission lines to measure the magnetic field distribution along the direction of the transmission lines. If results measured by k electromagnetic sensors in each row are consistent (within an acceptable measurement error range), it indicates that the UAV is flying along a position parallel to the transmission lines; otherwise, the UAV flight status needs to be adjusted. Based on magnetic field data measured by j electromagnetic sensors in each column, a gradient direction of the magnetic field gradient is analyzed, to determine whether to adjust a flight altitude of the UAV, ensuring that the UAV is at an altitude the same as the transmission lines. The positional relationship between the UAV and the transmission lines is shown in FIGS. 2A-2C. In FIGS. 2A-2C, jk represents the electromagnetic sensor located at the j-th row and k-th column, and the direction of the arrow indicates the direction of magnetic field enhancement. In FIG. 2A, the magnetic field data measured by the electromagnetic sensor matrix shows an enhancement trend from the first row to the j-th row; in FIG. 2B, the magnetic field data measured by the electromagnetic sensor matrix shows a weakening trend from the first row to the j-th row; in FIG. 2C, the magnetic field data measured by the electromagnetic sensor located in the middle position of the matrix rows is maximum.

The second electromagnetic sensor matrix 2 perpendicular to the transmission lines is an m×n-order matrix composed of m×n electromagnetic sensors, where m and n are both natural numbers, with m representing the number of rows, preferably within a range of [3, 5], and n representing the number of columns, preferably within a range of [5, 10]. In the second electromagnetic sensor matrix 2 perpendicular to the transmission lines, the electromagnetic sensors are arranged at equal spacing to form an m×n-order matrix within the vertical profile of the transmission lines.

By using the n columns of electromagnetic sensors arranged laterally in the second electromagnetic sensor matrix 2 perpendicular to the transmission lines, lateral characteristic parameters of the magnetic field are dynamically measured, and a lateral magnetic field gradient is calculated according to the following formula:

$${G}_{x} ( x , y ) = H ( x + 1 , y ) - H ( x - 1 , y )$$

where H(x, y) represents a characteristic value of a magnetic field at (x, y), and Gₓ(x, y) represents a lateral gradient of the magnetic field at (x, y). (x, y) represents a position of each electromagnetic sensor in the second electromagnetic sensor matrix 2 in the vertical profile of the transmission lines.

By using the m rows of electromagnetic sensors arranged longitudinally in the second electromagnetic sensor matrix 2 perpendicular to the transmission lines, longitudinal characteristic parameters of the magnetic field are dynamically measured, and a longitudinal magnetic field gradient is calculated according to the following formula:

$${G}_{y} ( x , y ) = H ( x , y + 1 ) - H ( x , y - 1 )$$

where H(x, y) represents a characteristic value of the magnetic field at (x, y), and G_{y}(x, y) represents a longitudinal gradient of the magnetic field at (x, y).

Based on the lateral magnetic field gradient and the longitudinal magnetic field gradient, the gradient amplitude and gradient direction of the magnetic field at (x, y) in space are calculated according to the following formula:

$$G ( x , y ) = \sqrt{{G}_{x}^{2} ( x , y ) + {G}_{y}^{2} ( x , y )}$$

$$α ( x , y ) = {tan}^{- 1} \frac{{G}_{y} ( x , y )}{{G}_{x} ( x , y )}$$

where G(x, y) represents a gradient amplitude value of the magnetic field at (x, y), and a (x, y) represents a gradient direction of the magnetic field at (x, y).

By measuring the magnetic field distribution parallel to the transmission lines using the first electromagnetic sensor matrix 1 parallel to the transmission lines and measuring the magnetic field distribution within the vertical profile of the transmission lines using the second electromagnetic sensor matrix 2 perpendicular to the transmission lines, dynamic measurement of the magnetic field distribution characteristics within the vertical profile of the transmission lines is achieved while considering the calibration of the UAV flight status. Based on the characteristic that the magnetic field gradient direction within the vertical profile of the transmission lines points towards the transmission lines, the position of the transmission lines is identified.

It is easy for those skilled in the art to understand that the above-mentioned contents are merely the preferred examples of the present disclosure, and are not intended to limit the present disclosure. Any modifications, equivalent substitutions and improvements made within the spirit and principles of the present disclosure should fall within the protection scope of the present disclosure.

What is claimed is:

1. A dynamic measurement method for a spatial magnetic field of transmission lines based on a two-dimensional electromagnetic sensor matrix, wherein a first electromagnetic sensor matrix is arranged parallel to transmission lines and is used for calibrating an unmanned aerial vehicle (UAV) flight status, while a second electromagnetic sensor matrix is arranged perpendicular to the transmission lines and is used for measuring magnetic field distribution characteristics within a vertical profile of the transmission lines; the first electromagnetic sensor matrix parallel to the transmission lines and the second electromagnetic sensor matrix perpendicular to the transmission lines form a two-dimensional electromagnetic sensor matrix; and dynamic measurement for a spatial magnetic field of the transmission lines is achieved through the two-dimensional electromagnetic sensor matrix during UAV flight.

2. The dynamic measurement method for a spatial magnetic field of transmission lines based on a two-dimensional electromagnetic sensor matrix according to claim 1, wherein the first electromagnetic sensor matrix is a j×k-order matrix formed by j×k electromagnetic sensors, and j and k are both natural numbers within a range of [3, 5], with j representing the number of rows and k representing the number of columns.

3. The dynamic measurement method for a spatial magnetic field of transmission lines based on a two-dimensional electromagnetic sensor matrix according to claim 2, wherein the calibration of the UAV flight status comprises: measuring a magnetic field distribution parallel to the transmission lines by using k electromagnetic sensors in each row of electromagnetic sensor matric containing j rows, wherein if results measured by the k electromagnetic sensors in each row are consistent, it indicates that a UAV is flying along a position parallel to the transmission lines, and if the results are inconsistent, the UAV flight status is adjusted; measuring a magnetic field distribution parallel to the transmission lines by using j electromagnetic sensors in each column of electromagnetic sensor matric containing k columns, and analyzing a magnetic field gradient direction to determine whether it is necessary to adjust a flight altitude of the UAV to keep the UAV at an altitude the same as the transmission lines.

4. The dynamic measurement method for a spatial magnetic field of transmission lines based on a two-dimensional electromagnetic sensor matrix according to claim 1, wherein the second electromagnetic sensor matrix is an m×n-order matrix formed by m×n electromagnetic sensors, and m and n are both natural numbers, with m representing the number of rows, within a range of [3, 5], and n representing the number of columns, within a range of [5, 10].

5. The dynamic measurement method for a spatial magnetic field of transmission lines based on a two-dimensional electromagnetic sensor matrix according to claim 4, wherein the dynamic measurement comprises dynamically measuring a gradient amplitude value and a gradient direction of the spatial magnetic field of the transmission lines by using m rows of electromagnetic sensors and n columns of electromagnetic sensors arranged in the second electromagnetic sensor matrix perpendicular to the transmission lines, with a calculation formula as follows:
$$\{ \begin{matrix}{G}_{x} ( x , y ) = H ( x + 1 , y ) - H ( x - 1 , y ) \\ {G}_{y} ( x , y ) = H ( x , y + 1 ) - H ( x , y - 1 )\end{matrix}$$
$$G ( x , y ) = \sqrt{{G}_{x}^{2} ( x , y ) + {G}_{y}^{2} ( x , y )}$$
$$α ( x , y ) = {tan}^{- 1} \frac{{G}_{y} ( x , y )}{{G}_{x} ( x , y )}$$
wherein H(x, y) represents a characteristic value of a magnetic field at (x, y), Gₓ(x, y) represents a lateral gradient of the magnetic field at (x, y), G_{y}(x, y) represents a longitudinal gradient of the magnetic field at (x, y), G(x, y) represents a gradient amplitude value of the magnetic field at (x, y), α(x, y) represents a gradient direction of the magnetic field at (x, y), and (x, y) represents a position of each electromagnetic sensor in the second electromagnetic sensor matrix in the vertical profile of the transmission lines.

6. The dynamic measurement method for a spatial magnetic field of transmission lines based on a two-dimensional electromagnetic sensor matrix according to claim 2, wherein the second electromagnetic sensor matrix is an m×n-order matrix formed by m×n electromagnetic sensors, and m and n are both natural numbers, with m representing the number of rows, within a range of [3, 5], and n representing the number of columns, within a range of [5, 10].

7. The dynamic measurement method for a spatial magnetic field of transmission lines based on a two-dimensional electromagnetic sensor matrix according to claim 3, wherein the second electromagnetic sensor matrix is an m×n-order matrix formed by m×n electromagnetic sensors, and m and n are both natural numbers, with m representing the number of rows, within a range of [3, 5], and n representing the number of columns, within a range of [5, 10].

8. The dynamic measurement method for a spatial magnetic field of transmission lines based on a two-dimensional electromagnetic sensor matrix according to claim 6, wherein the dynamic measurement comprises dynamically measuring a gradient amplitude value and a gradient direction of the spatial magnetic field of the transmission lines by using m rows of electromagnetic sensors and n columns of electromagnetic sensors arranged in the second electromagnetic sensor matrix perpendicular to the transmission lines, with a calculation formula as follows:
$$\{ \begin{matrix}{G}_{x} ( x , y ) = H ( x + 1 , y ) - H ( x - 1 , y ) \\ {G}_{y} ( x , y ) = H ( x , y + 1 ) - H ( x , y - 1 )\end{matrix}$$
$$G ( x , y ) = \sqrt{{G}_{x}^{2} ( x , y ) + {G}_{y}^{2} ( x , y )}$$
$$α ( x , y ) = {tan}^{- 1} \frac{{G}_{y} ( x , y )}{{G}_{x} ( x , y )}$$
wherein H(x, y) represents a characteristic value of a magnetic field at (x, y), Gₓ(x, y) represents a lateral gradient of the magnetic field at (x, y), G_{y}(x, y) represents a longitudinal gradient of the magnetic field at (x, y), G(x, y) represents a gradient amplitude value of the magnetic field at (x, y), α(x, y) represents a gradient direction of the magnetic field at (x, y), and (x, y) represents a position of each electromagnetic sensor in the second electromagnetic sensor matrix in the vertical profile of the transmission lines.

9. The dynamic measurement method for a spatial magnetic field of transmission lines based on a two-dimensional electromagnetic sensor matrix according to claim 7, wherein the dynamic measurement comprises dynamically measuring a gradient amplitude value and a gradient direction of the spatial magnetic field of the transmission lines by using m rows of electromagnetic sensors and n columns of electromagnetic sensors arranged in the second electromagnetic sensor matrix perpendicular to the transmission lines, with a calculation formula as follows:
$$\{ \begin{matrix}{G}_{x} ( x , y ) = H ( x + 1 , y ) - H ( x - 1 , y ) \\ {G}_{y} ( x , y ) = H ( x , y + 1 ) - H ( x , y - 1 )\end{matrix}$$
$$G ( x , y ) = \sqrt{{G}_{x}^{2} ( x , y ) + {G}_{y}^{2} ( x , y )}$$
$$α ( x , y ) = {tan}^{- 1} \frac{{G}_{y} ( x , y )}{{G}_{x} ( x , y )}$$
wherein H(x, y) represents a characteristic value of a magnetic field at (x, y), Gₓ(x, y) represents a lateral gradient of the magnetic field at (x, y), G_{y}(x, y) represents a longitudinal gradient of the magnetic field at (x, y), G(x, y) represents a gradient amplitude value of the magnetic field at (x, y), α(x, y) represents a gradient direction of the magnetic field at (x, y), and (x, y) represents a position of each electromagnetic sensor in the second electromagnetic sensor matrix in the vertical profile of the transmission lines.
